(19) United States
(12) Patent Application Publication
(10) Pub. No.: US 2025/0364376 A1
(43) Pub. Date: Nov. 27, 2025

(54) INTEGRATED CIRCUIT PACKAGE WITH SPLIT DIE ATTACH PADDLE

(71) Applicant: Allegro MicroSystems, LLC, Manchester, NH (US)

(72) Inventors: Weidong Wang, Westford, MA (US); Tonkla Faekrathok, Nakhon Ratchasima Province (TH); Natasha Healey, Manchester, NH (US); Mongkolwattana Manoyot, Pathum Thani Province (TH)

(73) Assignee: Allegro MicroSystems, LLC, Manchester, NH (US)

(21) Appl. No.: 18/672,430

(22) Filed: May 23, 2024

(51) Int. Cl. H01L 23/495; G01R 33/06; H01L 23/00

(52) U.S. Cl. CPC H01L 23/49503; G01R 33/06; H01L 24/48; H01L 24/85; H01L 2224/48175; H01L 2224/85

(57) ABSTRACT

An integrated circuit package includes a lead frame with a split die-attach paddle (DAP) that supports a semiconductor die with one or more magnetic field sensing elements. The split paddle reduces magnetic reluctance for enhancing coupling to the die and reducing eddy currents. The package provides mechanical stability to prevent die tilt, limiting sensing errors and protecting the die from stress from downstream mechanical forces during test and assembly pick processes. The mechanical stability is provided by one or more leads, strip tie-bars and/or band bars.

### BACKGROUND

As is known, sensors are used in various types of devices to measure and monitor properties of systems in a wide variety of applications. For example, sensors have become common in products that rely on electronics in their operation, such as automotive control systems. Examples of automotive applications are detection of wheel speed for antilock braking systems and four-wheel steering systems, and the speed and direction of transmission gears.

Some sensors monitor properties by detecting a magnetic field associated with proximity or movement of a target object with respect to one or more magnetic field sensing elements. In an automotive application, the sensor output signals can be coupled to an engine control unit (ECU) for further processing, such as detection of gear or wheel speed, direction and/or vibration, and current sensing.

Some sensors with magnetic field sensing elements are assembled in planar integrated circuit (IC) packages, such as dual in-line packages (DIP) or quad in-line packages (QIP). Such packages have footprints that can occupy valuable space on the substrate or printed circuit board (PCB). Planar packages, like DIP and QIP, adequately sense magnetic fields in two dimensions, for example x and y dimensions, however such packages are less effective in sensing fields in all three dimensions, such as x, y and z dimensions.

### SUMMARY

Aspects of the present disclosure relate to integrated circuit packages that provide reliable assembly of high-performance magnetic sensor die into single in-line packages (SIP). According to certain aspects, a lead frame may include a split die-attach paddle (DAP) that supports a semiconductor die with one or more magnetic field sensing elements.

According to one aspect, an SIP may include a lead frame having a die attach DAP and signal leads. The DAP may have a first portion with a first DAP surface and a second portion with a second DAP surface. The DAP may further include a split defined between the first and second portions. A semiconductor die may have a die surface adjacent to the first DAP surface and the second DAP surface. The semiconductor die may include at least one magnetic field sensing element supported by the semiconductor die. The magnetic field sensing element may be configured to sense a magnetic field and generate an output signal.

The SIP may include one or more of the following features alone or in combination. The split may entirely separate the first portion and the second portion of the DAP. The split may partially separate the first portion and the second portion. The at least one magnetic field sensing element may be disposed adjacent to the split. The split may have a first width and a second width. The at least one magnetic field sensing element may be disposed adjacent to the first width of the split. The semiconductor die may include a first magnetic field sensing element and a second magnetic field sensing element. The split may have a first width, a second width, and a third width. The first magnetic field sensing element may be disposed adjacent to the first width and the second magnetic field sensing element may be disposed adjacent to the third width. The first width may be substantially equal to the third width. The split may be substantially hourglass shaped. The split may have a narrowed region. The DAP may include at least one of the signal leads. The semiconductor die may be electrically coupled to the lead frame. The semiconductor die may be electrically coupled to the lead frame by one or more wire bonds. The one or more wire bonds may electrically couple the semiconductor die to each of the signal leads. The signal leads may be adapted to electrically couple the lead frame to a substrate and wherein the magnetic field is orthogonal to the substrate. The DAP may be adapted to substantially eliminate a magnetic reluctance between the DAP and the at least one magnetic field sensing element. The semiconductor die may be disposed on the DAP in a chip-on-lead configuration.

According to another aspect, a method of manufacturing a SIP IC package is provided. The method may include providing a lead frame comprising a DAP and signal leads. The DAP may have a first portion with a first DAP surface and a second portion with a second DAP surface. The DAP may further include a split defined between the first and second portions. A semiconductor die having a die surface may be positioned adjacent to the first DAP surface and the second DAP surface. The semiconductor die may support at least one magnetic field sensing element. The magnetic field sensing element may be configured to sense a magnetic field and generate an output signal.

The method may further include one or more of the following features alone or in combination. The split may entirely separate the first portion and the second portion of the DAP. The split may partially separate the first portion and the second portion. The at least one magnetic field sensing element may be disposed adjacent to the split. The split may have a first width and a second width. The at least one magnetic field sensing element may be disposed adjacent to the first width of the split. The semiconductor die may include a first magnetic field sensing element and a second magnetic field sensing element. The split may have a first width, a second width, and a third width. The first magnetic field sensing element may be disposed adjacent to the first width and the second magnetic field sensing element may be disposed adjacent to the third width. The first width may be substantially equal to the third width. The split may be substantially hourglass shaped. The split may have a narrowed region. The DAP may include at least one of the signal leads. The semiconductor die may be electrically coupled to the lead frame. The semiconductor die may be electrically coupled to the lead frame by one or more wire bonds. The one or more wire bonds may electrically couple the semiconductor die to each of the signal leads. The signal leads may be adapted to electrically couple the lead frame to a substrate and wherein the magnetic field is orthogonal to the substrate. The DAP may be adapted to substantially eliminate a magnetic reluctance between the DAP and the at least one magnetic field sensing element. The semiconductor die may be disposed on the DAP in a chip-on-lead configuration.

According to another aspect, an SIP IC may include a lead frame having a DAP and signal leads. The DAP may have a first portion with a first DAP surface and a second portion with a second DAP surface. The DAP may further include a split defined between the first and second portions. A semiconductor die may have a die surface adjacent to the DAP surface and the second DAP surface. The semiconductor die may include a first magnetic field sensing element and a second magnetic field sensing element supported by the semiconductor die. The first magnetic field sensing element and the second magnetic field sensing element may be disposed adjacent to the split. The first magnetic field sensing element and the second magnetic field sensing element may be operable to generate one or more output signals. The one or more output signals may be indicative of a magnetic field associated with an object.

### BRIEF DESCRIPTION OF THE DRAWINGS

The foregoing features of the disclosure, as well as the disclosure itself may be more fully understood from the following detailed description of the drawings. The drawings aid in explaining and understanding the disclosed technology. Since it is often impractical or impossible to illustrate and describe every possible embodiment, the provided figures depict one or more exemplary embodiments. Accordingly, the figures are not intended to limit the scope of the invention. Like numbers in the figures denote like elements.

FIG. 1 is a top plan view of a three-lead single in-line package (SIP) according to aspects of the present disclosure; and

FIG. 2 is a top plan view of a four-lead SIP according to aspects of the present disclosure.

### DETAILED DESCRIPTION

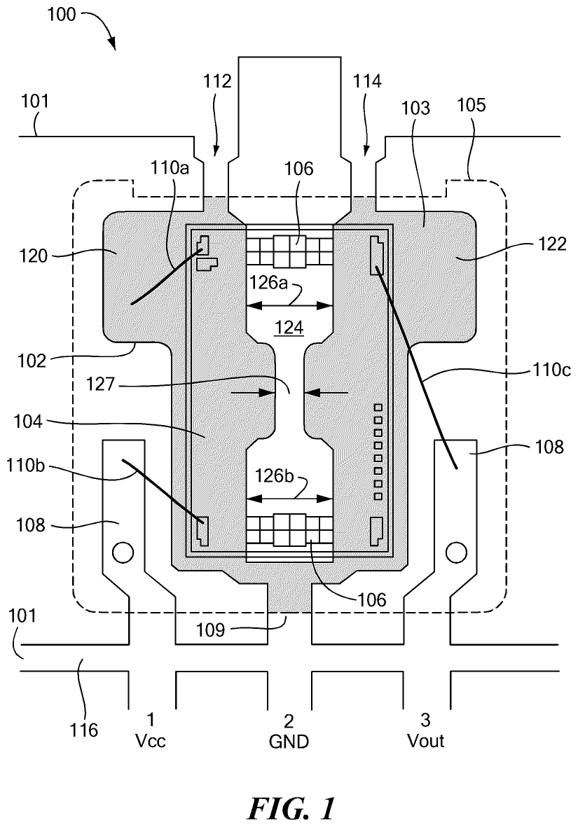

Referring now to FIG. 1, an IC package 100 may include a lead frame 102 having a die attach paddle (DAP) 103 and one or more signal leads 108. According to one or more aspects of the present disclosure, IC package 100 may include a split DAP 103 configured to reduce or substantially eliminate magnetic reluctance for allowing enhanced coupling to a sensor die, such as a Hall sensor or other magnetic sensing element. The split DAP 103 may be configured further to reduce eddy currents, provide mechanical stability to prevent die tilt, and protect the die from stress and downstream mechanical forces caused by test and assembly pick-and-place processes using a chip-on-lead configuration.

According to one aspect, the IC package 100 may be a single inline package (SIP) defined by an encapsulant material 105. As shown in FIG. 1, the lead frame 102 may be cut out from a strip 101 of conductive material such as Copper, Aluminum, or iron-Nickle alloys. The features of the lead frame 102 may be formed by various methods such as stamping or etching. The lead frame 102 may remain coupled to the strip 101 by one or more tying structures, such as tie bars 112, 114, and a band bar 116. According to one aspect, the IC package 100 may comprise a three-lead package in which the one or more signal leads 108 are coupled to the band bar 116. The DAP 103 may remain coupled to the strip 101 by the tie bars 112, 114 and a ground lead 109. It is understood that mechanical stability during fabrication may be provided by the ground lead 109 of the DAP 103 and the tie bars 112, 114. After fabrication, the IC package 100 may be separated from the strip 101 by cutting the tie bars 112, 114 and band bar 116, leaving exposed the signal leads 108 and ground lead 109 for connection to a printed circuit board (PCB) or other substrate.

According to one aspect, the DAP 103 may include or define a first portion 120 and a second portion 122. The DAP may further include or define a split 124 between the first portion 120 and the second portion 122. The split 124, according to one aspect, may have an hourglass shape including a first width 126a and a second width 126b greater than a third width 127 between them. The first portion 120 and the second portion 122 of the DAP 103 may be coupled at or near the end of the split 124 at the ground lead 109 to form a U-shape.

A semiconductor die 104 may be disposed adjacent to the lead frame 102. The semiconductor die 104 may support or otherwise include one or more magnetic sensing elements 106 for sensing a magnetic field associated with an object or other target and generate an output signal indicative of the magnetic field.

According to one aspect, the magnetic field sensing element 106 can be a single element or can include more than one element, such as a dual Hall element or a quad Hall element and/or one or more magnetoresistance elements as are sometimes arranged in a bridge configuration and as may be used to implement differential magnetic field sensing.

According to one aspect, the magnetic field sensing elements 106 may include one or more elements that are positioned adjacent to the split 124. As shown in FIG. 1, the semiconductor die 104 may be disposed adjacent to the DAP 103 of the lead frame 102 such that the magnetic field sensing elements 106 are aligned with the first width 126a and second width 126b, respectively, of the hourglass shaped split 124. Accordingly, the DAP 103 does not extend between the magnetic field sensing elements and the encapsulate material 105. The alignment of the magnetic field sensing elements 106 with the split 124 may reduce or substantially eliminate any magnetic reluctance between the magnetic field sensing elements 106 and the object or target, and thereby enhance or substantially increase the magnetic coupling. The split 124 in the DAP 103 may also serve to reduce eddy currents decreasing the area in which eddy currents can flow.

According to one aspect, the split 124 in the DAP 103 may avoid any potential closed current loop in the lead frame 102 that may impact the performance of the magnetic field sensing elements 106. Further, the split 124 in the DAP 103 may be sized and shaped to reduce the chance of the die semiconductor die 104 cracking due to the unsupported area under the die 104. According to one aspect, the first width 126a and the second width 126b may be about as wide, or slightly wider than the width of the magnetic field sensing elements 106. For structural integrity the first width 126a and the second width 126b may have widths not substantially greater than the sensing elements 106. The third width 127 of the split 124 may be about the thickness of the lead frame 102. Accordingly, the hourglass shape of the split 124 may reduce the chance of the semiconductor die 104 cracking while reducing the impact of any eddy currents on the die sensors. The split 124 may also prevent a closed current loop in the middle of the DAP 103.

According to one aspect, the semiconductor die 104 may be electrically coupled to the lead frame 102 by one or more wire bonds, collectively labeled 110. For example, the semiconductor die 104 may be coupled to the DAP 103, and the ground lead 109, by a first wire bond 110a. A second wire bond 110b may couple the semiconductor die to one of the signal leads 108 (e.g., V_{CC}) and a third wire bond 110c may couple the semiconductor die to another lead (e.g., V_{OUT}).

The IC package 100, as detailed above may be a single inline package. Accordingly, the IC package 100 may be mounted or coupled to a substrate or PCB substantially perpendicular to the surface of the substrate. According to one aspect, the perpendicular arrangement of the package 100, and the magnetic sensing elements 106, may allow for more effective magnetic field responses in three dimensions. For example, the perpendicular configuration may allow the magnetic sensing elements 106 to better sense magnetic fields in the z-direction (i.e., the direction perpendicular to the substrate). This is in contrast to planar sensor packages that lie flat against or adjacent to the substrate, such as dual inline or quad inline packages, which may not be able to sense z-direction magnetic fields effectively. For example, the package 100 may have better performance in the z-direction due to the increased distance between the magnetic field sensing elements 106. In contrast, dual in-line packages (DIP) and quad in-line packages (QIP) feature sensing elements in the same plane, which therefore may have less tolerance when sensing in the z-direction.

While the IC package 100 shown in FIG. 1 includes a three-lead package, one of skill in the art will recognize that the scope of the present application is not limited to such a configuration and an IC package may include any number of leads without out deviating from the scope of the disclosure. Further, one skilled in the art will recognize that additional shapes and dimensions of the IC package lead frame are possible and within the scope of the disclosure, including 3-lead, 4 mm by 4 mm×1.5 mm package, or a 4-lead, 5.21 mm by 3.43 mm by 1.55 mm package

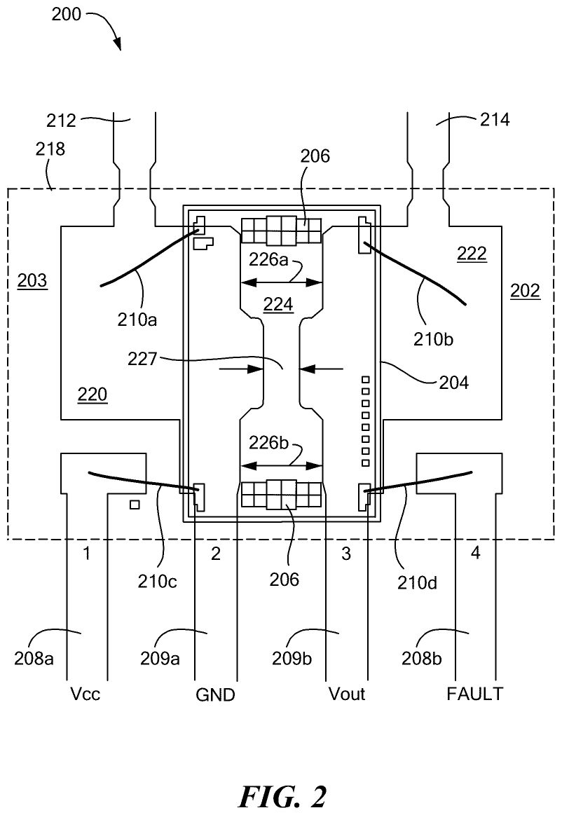

Referring now to FIG. 2, an IC package 200 may include four leads 208a, 208b, 209a, 209b. Similarly to the IC package shown in FIG. 1, the IC package 200 may be an SIP. The IC package 200 may further include a lead frame 202, a semiconductor die 204 supporting one or more magnetic field sensing elements 206, and encapsulate material 218 encapsulating the lead frame 202 and semiconductor die 204. The semiconductor die 204, including one or more magnetic sensing elements 206 and the molding 218, may be substantially similar or similarly configured as those described in connection with the IC package of FIG. 1.

The IC package 200, according to one aspect may include a lead frame 202 having signal leads 208a, 208b (e.g., V_{CC} and Fault, respectively) and a DAP 203. The DAP 203 may include a first portion 220 and a second portion 222 with a split 224 defined between them. The split 224, according to one aspect, may extend an entire length of the DAP 203 such that the first portion 220 and the second portion 222 are separated entirely from each other. The split 224, according to one aspect, may have an hourglass shape including a first width 226a and a second width 226b, both greater than a third width 227 between them.

For mechanical stability during fabrication and assembly, the IC package 200 may be formed on or from a lead frame fabrication strip (not shown) including one or more tie bars 212, 214 and a band bar (not shown). The first portion 220 of the DAP 203 may be coupled to a fabrication strip by a first tie bar 212 and may further form or be coupled to a signal lead 209a (e.g., a ground lead). The second portion 222 of the DAP 203 may be coupled to the fabrication strip by a second tie bar 214 and may further form or be coupled to a signal lead 209b (e.g., V_{OUT}). The signal leads 208a, 208b, 209a, 209b each may be coupled to the band bar.

According to one aspect, the magnetic field sensing elements 206 may include one or more elements that are positioned adjacent to the split 224 in the DAP. As shown in FIG. 2, the semiconductor die 204 may be disposed adjacent to the DAP 203 of the lead frame 202 such that the magnetic field sensing elements 206 are aligned with the first width 226a and second width 226b of the hourglass shaped split 224. The alignment of the magnetic field sensing elements 206 with the split 224 may decrease or substantially eliminate any magnetic reluctance between the magnetic field sensing elements 206 and the object or target, and thereby enhance or substantially increase the magnetic coupling. The split 224 in the DAP 203 may also serve to reduce eddy currents.

According to one aspect, the semiconductor die 204 may be electrically coupled to the lead frame through one or more wire bonds, collectively labeled 210. For example, a first wire bond 210a may couple the semiconductor die 204 to the first portion 220 of the DAP 203 which is coupled to a signal lead 209a. A second wire bond 210b may couple the semiconductor die 204 to a signal lead 209b. A third wire bond 210c may couple the semiconductor die 204 to a signal lead 208a and a fourth wire bond 210d may couple the semiconductor die 204 to a signal lead 208b.

The IC packages described herein may provide for packages and lead frame designs to broaden the size and scope of magnetic field sensor package platforms. Additionally, as detailed above, aspects of the IC packages provide for magnetic field sensors that effectively capture and output magnetic field signals in all three dimensions (e.g., x, y, and z dimensions). The IC packages described may also provide magnetic sensor devices with robust package and die strength.

The detailed description set forth above, in connection with the appended drawings, is intended as a description of various configurations and is not intended to represent the only configurations in which the concepts described herein may be practiced. The detailed description includes specific details for providing a thorough understanding of the various concepts. It will be apparent to those skilled in the art, however, that these concepts may be practiced without these specific details. In some instances, well-known structures and components are shown in block diagram form in order to avoid obscuring such concepts.

As used herein, the term “magnetic field sensor” or simply “sensor” is used to describe a circuit that uses one or more magnetic field sensing elements, generally in combination with other circuits. The magnetic field sensor can be, for example, a rotation detector, a movement detector, or a proximity detector. A rotation detector (or movement detector) can sense passing target objects, for example, magnetic domains of a ring magnet or a ferromagnetic target (e.g., gear teeth) where the magnetic field sensor is used in combination with a back-bias or other magnet and can determine target movement speed. Ferromagnetic objects described herein can have a variety of forms, including, but not limited to, a ring magnet having one or more pole pair, and a gear having two or more gear teeth. Ferromagnetic gears are used in some examples below to show a rotating ferromagnetic object having ferromagnetic features, i.e., teeth. However, in other embodiments, the gear can be replaced with a ring magnet having at least one pole pair. Also, linear arrangements of ferromagnetic objects are possible that move linearly.

As used herein, the term “magnetic field sensing element” is used to describe a variety of electronic elements that can sense a magnetic field. The magnetic field sensing element can be, but is not limited to, a Hall effect element, a magnetoresistance element, a magnetotransistor, or an inductive coil. As is known, there are different types of Hall effect elements, for example, a planar Hall element, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, for example, a spin valve, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb).

As is known, some of the above-described magnetic field sensing elements tend to have an axis of maximum sensitivity parallel to a substrate or in the plane of the substrate that supports the magnetic field sensing element, and others of the above-described magnetic field sensing elements tend to have an axis of maximum sensitivity perpendicular to a substrate that supports the magnetic field sensing element. In particular, planar Hall elements tend to have axes of maximum sensitivity perpendicular to a substrate, while metal based or metallic magnetoresistance elements (e.g., GMR, TMR, AMR) and vertical Hall elements tend to have axes of maximum sensitivity parallel to a substrate.

As used herein, the term “magnetic field signal” is used to describe any signal that results from a magnetic field experienced by a magnetic field sensing element.

It is noted that various connections and positional relationships (e.g., over, below, adjacent, etc.) may be used to describe elements and components in the description and drawings. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

Also, the following definitions and abbreviations are to be used for the interpretation of the claims and the specification. The terms “comprise,” “comprises,” “comprising, “include,” “includes,” “including,” “has,” “having,” “contains” or “containing,” or any other variation are intended to cover a non-exclusive inclusion. For example, an apparatus, a method, a composition, a mixture, or an article, that includes a list of elements is not necessarily limited to only those elements but can include other elements not expressly listed or inherent to such apparatus, method, composition, mixture, or article.

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it may affect such feature, structure, or characteristic in other embodiments whether explicitly described or not.

Use of ordinal terms such as “first,” “second,” “third,” etc., in the claims to modify a claim element does not by itself connote any priority, precedence, or order of one claim element over another, or a temporal order in which acts of a method are performed, but are used merely as labels to distinguish one claim element having a certain name from another element having a same name (but for use of the ordinal term) to distinguish the claim elements.

In the foregoing detailed description, various features of embodiments are grouped together in one or more individual embodiments for the purpose of streamlining the disclosure. This method of disclosure is not to be interpreted as reflecting an intention that the claims require more features than are expressly recited therein. Rather, inventive aspects may lie in less than all features of each disclosed embodiment.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

Having described implementations which serve to illustrate various concepts, structures, and techniques which are the subject of this disclosure, it will now become apparent to those of ordinary skill in the art that other implementations incorporating these concepts, structures, and techniques may be used. Accordingly, it is submitted that that scope of the patent should not be limited to the described implementations but rather should be limited only by the spirit and scope of the following claims.

What is claimed is:

1. A single in-line package (SIP) comprising:
a lead frame comprising a die attach paddle (DAP) and signal leads, the DAP having a first portion with a first DAP surface and a second portion with a second DAP surface, the DAP further comprising a split defined between the first and second portions; and
a semiconductor die having a die surface adjacent to the first DAP surface and the second DAP surface, the semiconductor die comprising at least one magnetic field sensing element supported by the semiconductor die, wherein the magnetic field sensing element is configured to sense a magnetic field and generate an output signal.

2. The SIP of claim 1 wherein the split entirely separates the first portion and the second portion of the DAP.

3. The SIP of claim 1 wherein the split partially separates the first portion and the second portion.

4. The SIP of claim 1 wherein the at least one magnetic field sensing element is disposed adjacent to the split.

5. The SIP of claim 1 wherein the split has a first width and a second width, the at least one magnetic field sensing element disposed adjacent to the first width of the split.

6. The SIP of claim 1 wherein the semiconductor die includes a first magnetic field sensing element and a second magnetic field sensing element.

7. The SIP of claim 6 wherein the split has a first width, a second width, and a third width, the first magnetic field sensing element disposed adjacent to the first width and the second magnetic field sensing element disposed adjacent to the third width.

8. The SIP of claim 7 wherein the first width is substantially equal to the third width.

9. The SIP of claim 1 wherein the split is substantially hourglass shaped.

10. The SIP of claim 1 wherein the split has a narrowed region.

11. The SIP of claim 1 wherein the DAP includes at least one of the signal leads.

12. The SIP of claim 1 wherein the semiconductor die is electrically coupled to the lead frame.

13. The SIP of claim 12 wherein the semiconductor die is electrically coupled to the lead frame by one or more wire bonds.

14. The SIP of claim 13 wherein the one or more wire bonds electrically couple the semiconductor die to each of the signal leads.

15. The SIP of claim 1 wherein the signal leads are adapted to electrically couple the lead frame to a substrate and wherein the magnetic field is orthogonal to the substrate.

16. The SIP of claim 1 wherein the DAP is adapted to substantially eliminate a magnetic reluctance between the DAP and the at least one magnetic field sensing element.

17. The SIP of claim 1 wherein the semiconductor die is disposed on the DAP in a chip-on-lead configuration.

18. A method of manufacturing a single in-line (SIP) integrated circuit (IC) package, the method comprising:
providing a lead frame comprising a die attach paddle (DAP) and signal leads, the DAP having a first portion with a first DAP surface and a second portion with a second DAP surface, the DAP further comprising a split defined between the first and second portions; and
positioning a semiconductor die having a die surface adjacent to the first DAP surface and the second DAP surface, wherein the semiconductor die supports at least one magnetic field sensing element, the magnetic field sensing element configured to sense a magnetic field and generate an output signal.

19. The method of claim 18 wherein the split entirely separates the first portion and the second portion of the DAP.

20. The method of claim 18 wherein the split partially separates the first portion and the second portion.

21. The method of claim 18 wherein the at least one magnetic field sensing element is disposed adjacent to the split.

22. The method of claim 18 wherein the split has a first width and a second width, the at least one magnetic field sensing element disposed adjacent to the first width of the split.

23. The method of claim 18 wherein the semiconductor die includes a first magnetic field sensing element and a second magnetic field sensing element.

24. The method of claim 23 wherein the split has a first width, a second width, and a third width, the first magnetic field sensing element disposed adjacent to the first width and the second magnetic field sensing element disposed adjacent to the third width.

25. The method of claim 24 wherein the first width is substantially equal to the third width.

26. The method of claim 18 wherein the split is substantially hourglass shaped.

27. The method of claim 18 wherein the split has a narrowed region.

28. The method of claim 18 wherein the DAP includes at least one of the signal leads.

29. The method of claim 18 wherein the semiconductor die is electrically coupled to the lead frame.

30. The method of claim 29 wherein the semiconductor die is electrically coupled to the lead frame by one or more wire bonds.

31. The method of claim 30 wherein the one or more wire bonds electrically couple the semiconductor die to each of the signal leads.

32. The method of claim 30 wherein the signal leads are adapted to electrically couple the lead frame to a substrate and wherein the magnetic field is orthogonal to the substrate.

33. The method of claim 18 wherein the DAP is adapted to substantially eliminate a magnetic reluctance between the DAP and the at least one magnetic field sensing element.

34. The method of claim 18 wherein the semiconductor die is disposed on the DAP in a chip-on-lead configuration.

35. A single in-line package (SIP) integrated circuit (IC) comprising:
a lead frame comprising a die attach paddle (DAP) and signal leads, the DAP having a first portion with a first DAP surface and a second portion with a second DAP surface, the DAP further comprising a split defined between the first and second portions; and
a semiconductor die having a die surface adjacent to the DAP surface and the second DAP surface, the semiconductor die comprising a first magnetic field sensing element and a second magnetic field sensing element supported by the semiconductor die, the first magnetic field sensing element and the second magnetic field sensing element disposed adjacent to the split,
wherein the first magnetic field sensing element and the second magnetic field sensing element are operable to generate one or more output signals, the one or more output signals indicative of a magnetic field associated with an object.
